(19) United States
(12) Patent Application Publication
(10) Pub. No.: US 2026/0090012 A1
(43) Pub. Date: Mar. 26, 2026

(54) SWITCHING ELEMENT

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP); NATIONAL INSTITUTE OF ADVANCED INDUSTRIAL SCIENCE AND TECHNOLOGY, Tokyo (JP); FUJI ELECTRIC CO., LTD., Kawasaki-shi (JP)

(72) Inventors: Eiji KAGOSHIMA, Nisshin-shi (JP); Misa TAKAHASHI, Chofu-shi (JP); Manami IWATA, Chofu-shi (JP); Shinsuke HARADA, Tsukuba-shi (JP); Syunki NARITA, Matsumoto-shi (JP)

(21) Appl. No.: 19/318,850

(22) Filed: Sep. 4, 2025

(30) Foreign Application Priority Data
Sep. 26, 2024 (JP) 2024-167844

(51) Int. Cl. H10D 30/66; H10D 62/17; H10D 62/832

(52) U.S. Cl. CPC H10D 30/668; H10D 62/393; H10D 62/8325

(57) ABSTRACT

A switching element includes a silicon carbide semiconductor substrate and a gate electrode facing the semiconductor substrate through a gate insulating film. The semiconductor substrate includes: an n-type source layer in contact with the gate insulating film; a p-type body layer in contact with the gate insulating film and the source layer; an n-type first drift layer in contact with the gate insulating film and the body layer, separated from the source layer by the body layer, and having an n-type impurity concentration of 8×10¹⁵ cm⁻³ or more; an n-type second drift layer in contact with the first drift layer from below and having an n-type impurity concentration of 12 to 26 times the n-type impurity concentration of the first drift layer; and an n-type drain layer disposed below the second drift layer and having a higher n-type impurity concentration than the second drift layer.

### CROSS REFERENCE TO RELATED APPLICATION

The present application claims the benefit of priority from Japanese Patent Application No. 2024-167844 filed on Sep. 26, 2024. The entire disclosures of the above application are incorporated herein by reference.

### TECHNICAL FIELD

The present disclosure relates to a switching element.

### BACKGROUND

It has been known that, when cosmic rays enter a switching element, electron-hole pairs are generated inside a semiconductor substrate, decreasing the breakdown voltage of the switching element.

### SUMMARY

The present disclosure describes a switching element. According to an aspect, a switching element includes: a semiconductor substrate made of silicon carbide; and a gate electrode facing the semiconductor substrate through a gate insulating film. The semiconductor substrate includes: a source layer of an n-type in contact with the gate insulating film; a body layer of a p-type in contact with the gate insulating film and the source layer; a first drift layer of the n-type that is in contact with the gate insulating film and the body layer, is separated from the source layer by the body layer, and has an n-type impurity concentration of 8×10¹⁵ cm⁻³ or more; a second drift layer of the n-type that is in contact with the first drift layer from below and has an n-type impurity concentration of 12 to 26 times the n-type impurity concentration of the first drift layer; and a drain layer of the n-type that is disposed below the second drift layer and has an n-type impurity concentration higher than that of the second drift layer.

### BRIEF DESCRIPTION OF DRAWINGS

Objects, features and advantages of the present disclosure will become more apparent from the following detailed description made with reference to the accompanying drawings, in which like parts are designated by like reference numbers and in which:

FIG. 1 is a graph showing a relationship between a concentration ratio B/A and an electric field strength E;

FIG. 2 is a cross-sectional view of a switching element according to a first embodiment;

FIG. 3 is a cross-sectional view of a switching element according to a modified example of the first embodiment;

FIG. 4 is a cross-sectional view of a switching element according to a second embodiment; and

FIG. 5 is a cross-sectional view of a switching element according to a third embodiment.

### DETAILED DESCRIPTION

It has been known that cosmic rays entering a switching element cause generation of electron-hole pairs inside a semiconductor substrate, decreasing the breakdown voltage of the switching element. In order to suppress the decrease in breakdown voltage due to the cosmic rays, it is conceivable to adjust distribution of an n-type impurity concentration in a drift layer.

The present disclosure provides a technique for further suitably suppressing a decrease in breakdown voltage due to cosmic rays in a switching element.

According to an aspect of the present disclosure, a switching element includes: a semiconductor substrate made of silicon carbide, and a gate electrode facing the semiconductor substrate through a gate insulating film. The semiconductor substrate includes: an n-type source layer in contact with the gate insulating film, a p-type body layer in contact with the gate insulating film and the source layer, an n-type first drift layer that is in contact with the gate insulating film and the body layer, is separated from the source layer by the body layer, and has an n-type impurity concentration of 8×10¹⁵ cm⁻⁻or more, an n-type second drift layer that is in contact with the first drift layer from below, and has an n-type impurity concentration of 12 to 26 times the n-type impurity concentration of the first drift layer, and an n-type drain layer that is disposed below the second drift layer and has an n-type impurity concentration higher than that of the second drift layer.

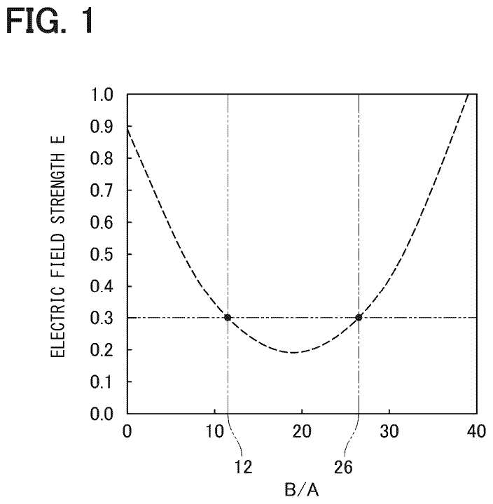

FIG. 1 shows a relationship between an electric field strength E generated inside a semiconductor substrate when cosmic rays have entered a switching element and a concentration ratio B/A. The concentration ratio B/A is a value obtained by dividing an n-type impurity concentration B in the second drift layer by an n-type impurity concentration A in the first drift layer. In FIG. 1, the relationship is shown as a standardized value where the electric field strength E is 1 when the concentration ratio B/A is 38. As shown in FIG. 1, the electric field strength E changes according to the concentration ratio B/A. The electric field strength E is at a minimum when the concentration ratio B/A is about 20. In the switching element described above, since the concentration ratio B/A is in a range of 12 to 26, the electric field strength E generated inside the semiconductor substrate when the cosmic rays have entered is low. Therefore, in such a switching element, the decrease in breakdown voltage caused by the cosmic rays can be suppressed.

### First Embodiment

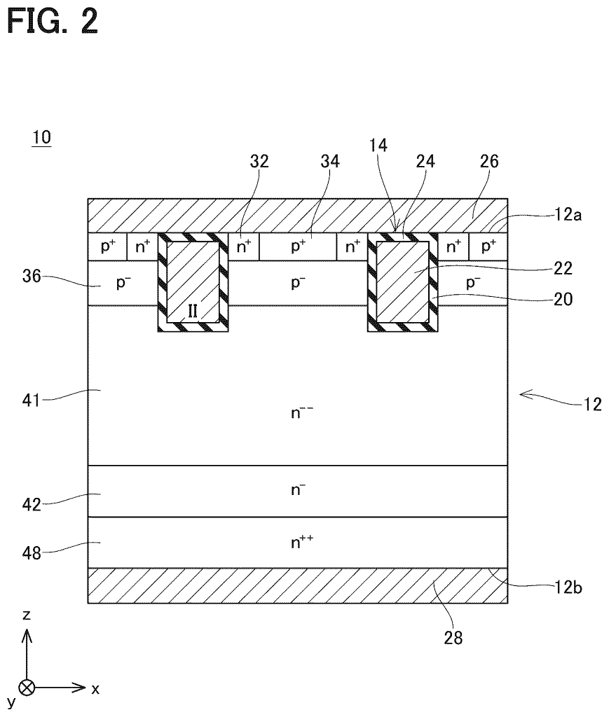

A switching element 10 according to a first embodiment shown in FIG. 2 is a trench gate-type metal oxide semiconductor field effect transistor (MOSFET). The switching element 10 is designed for use in the stratosphere or at higher altitudes (for example, outer space), and has a structure capable of suppressing the effects of cosmic rays. The switching element 10 includes a semiconductor substrate 12, a gate electrode 22, a gate insulating film 20, a source electrode 26, and a drain electrode 28.

The semiconductor substrate 12 is made of silicon carbide (SiC). In the following, a direction parallel to an upper surface 12a of the semiconductor substrate 12 is referred to as an x direction, and a direction parallel to the upper surface 12a and perpendicular to the x direction is referred to as a y direction. Also, a thickness direction of the semiconductor substrate 12, that is, a direction perpendicular to the x direction and the y direction is referred to as a z direction. The semiconductor substrate 12 is formed with multiple trenches 14 in the upper surface 12a. Each of the trenches 14 extends linearly along the y direction in the upper surface 12a. The trenches 14 are spaced apart from each other in the x direction.

The gate insulating film 20 covers an inner surface of each of the trenches 14. The gate electrode 22 is disposed inside of each of the trenches 14. The gate electrode 22 is insulated from the semiconductor substrate 12 by the gate insulating film 20. An upper surface of the gate electrode 22 is covered with an interlayer insulating film 24.

The source electrode 26 covers the upper surface 12a of the semiconductor substrate 12. The source electrode 26 is insulated from the gate electrode 22 by the interlayer insulating film 24. The drain electrode 28 covers a lower surface 12b of the semiconductor substrate 12.

The semiconductor substrate 12 has multiple source layers 32, multiple contact layers 34, a body layer 36, a first drift layer 41, a second drift layer 42, and a drain layer 48.

Each of the source layers 32 is an n-type layer having a high n-type impurity concentration. Each of the source layers 32 is in ohmic contact with the source electrode 26 at the upper surface 12a. Each of the source layers 32 is in contact with the gate insulating film 20 at the upper end of the side surface of the corresponding trench 14.

Each of the contact layers 34 is a p-type layer having a high p-type impurity concentration. Each of the contact layers 34 is in ohmic contact with the source electrode 26 at the upper surface 12a.

The body layer 36 is a p-type layer having a p-type impurity concentration lower than that of the contact layers 34. The body layer 36 is disposed below the source layers 32 and the contact layers 34. The body layer 36 is in contact with the source layers 32 and the contact layers 34 from below. The body layer 36 is in contact with the gate insulating film 20 on the side surface of the trench 14 below the source layer 32.

The first drift layer 41 is an n-type layer having an n-type impurity concentration lower than that of the source layer 32. The n-type impurity concentration of the first drift layer 41 is referred to as an n-type impurity concentration A. The n-type impurity concentration A is 8×10¹⁵ cm⁻³ or more. For example, the n-type impurity concentration A of the first drift layer 41 may be 3×10¹⁶ cm⁻³ or more. For example, the n-type impurity concentration A of the first drift layer 41 may be 1×10¹⁸ cm⁻³ or less. The first drift layer 41 is disposed below the body layer 36. The first drift layer 41 is in contact with the body layer 36 from below. The first drift layer 41 is separated from the source layers 32 by the body layer 36. The first drift layer 41 is in contact with the gate insulating film 20 on the side surface of the trench 14 below the body layer 36. The first drift layer 41 is distributed from a position in contact with the body layer 36 to a position below the lower ends of the trenches 14.

The second drift layer 42 is an n-type layer, and is in contact with the first drift layer 41 from below. The n-type impurity concentration B of the second drift layer 42 is referred to as an n-type impurity concentration B. The n-type impurity concentration B is at least 12 and at most 26 times the n-type impurity concentration A of the first drift layer 41. That is, the n-type impurity concentration B of the second drift layer 42 is set so that the concentration ratio B/A is in a range from 12 to 26.

The drain layer 48 is an n-type layer having an n-type impurity concentration higher than that of the second drift layer 42. The drain layer 48 is in contact with the second drift layer 42 from below. The n-type impurity concentration of the drain layer 48 is 1×10¹⁹ cm⁻³ or more. The drain layer 48 is in ohmic contact with the drain electrode 28 at the lower surface 12b of the semiconductor substrate 12.

When the switching element 10 is in use, a higher potential is applied to the drain electrode 28 than to the source electrode 26. When a potential equal to or higher than a gate threshold is applied to the gate electrode 22, a channel is formed in the body layer 36 in an area adjacent to the gate insulating film 20. Thus, the source layer 32 and the first drift layer 41 are connected through the channel. As a result, electrons flow from the source layer 32 to the drain layer 48 through the channel, the first drift layer 41, and the second drift layer 42. That is, the switching element 10 is turned on. When the potential of the gate electrode 22 is decreased to a potential lower than the gate threshold, the channel disappears and the switching element 10 is turned off. When the switching element 10 is turned off, a depletion layer extends from the body layer 36 into the drift layers 41 and 42. The depletion layer maintains the voltage applied between the drain electrode 28 and the source electrode 26.

When cosmic rays enter the drift layers 41 and 42 of the switching element 10 in the off state, electron-hole pairs are generated inside the drift layers 41 and 42. As a result, an electric field is generated inside the drift layers 41 and 42. When the electric field is generated due to the entry of the cosmic rays in this way, dielectric breakdown occurs in the switching element 10 even if the drain-source voltage is equal to or lower than a rated value. In this way, the breakdown voltage of the switching element 10 is lowered by the cosmic rays entering the drift layers 41 and 42.

FIG. 1 shows the results of a simulation of the relationship between the electric field strength E and the concentration ratio B/A that occurs when cosmic rays have entered the drift layers 41 and 42 in a configuration in which the n-type impurity concentration A of the first drift layer 41 is 8×10¹⁵ cm⁻³ cm or more. As shown in FIG. 1, the electric field strength E is at a minimum when the concentration ratio B/A is about 20. When the concentration ratio B/A is in the range of 12 to 26, the rate of change of the electric field strength E with respect to the concentration ratio B/A is small, and the electric field strength E is stable at a low value of 0.3 or less. Therefore, when the concentration ratio B/A is adjusted to be at least 12 and at most 26, the electric field strength E generated due to the cosmic rays entering the drift layers 41 and 42 can be suppressed. In the switching element 10 of the first embodiment, the concentration ratio B/A is at least 12 and at most 26. Therefore, the electric field strength E generated due to the cosmic rays is low, and the decrease in breakdown voltage due to the cosmic rays is suppressed. The concentration ratio B/A may be in a range from 14 to 24. In this case, the electric field strength E is stable at a low value of 0.25 or less.

The thickness of each semiconductor layer is arbitrary, but the thickness of each layer can be set as follows. The thicknesses of the source layer 32 and the contact layer 34 may be from 400 nm to 600 nm. The thickness of the body layer 36 may be from 300 nm to 1000 nm. The thickness of the first drift layer 41 may be 3 μm to 10μm. The thickness of the second drift layer 42 may be from 0.3 μm to 2.0 μm. The thickness of the drain layer 48 may be from 50 μm to 300 μm. The switching element has a breakdown voltage class of 1200 V to 3300 V.

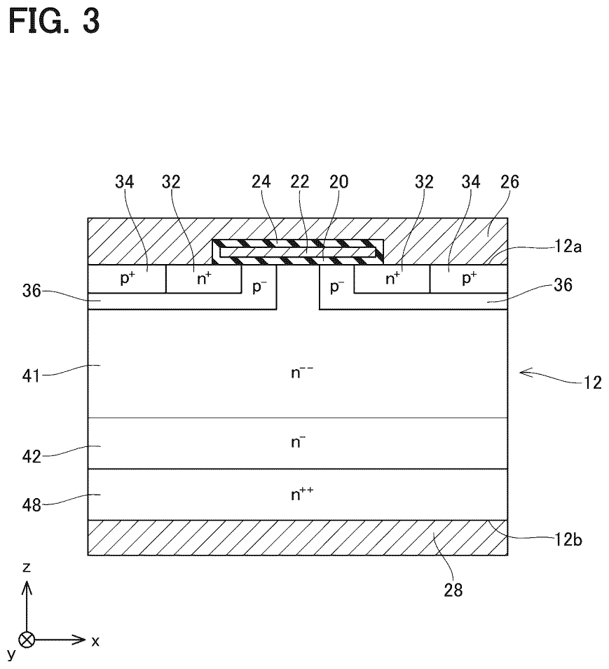

In the first embodiment, the switching element having a trench-type gate structure has been exemplified. As another example, the concentration ratio B/A may be adjusted to be at least 12 and at most 26 in a switching element having a planar-type gate structure as shown in FIG. 3. In addition, also in any switching element having an upper structure different from those shown in FIGS. 2 and 3, the concentration ratio B/A disclosed in this specification can be applied to suppress the decrease in breakdown voltage due to cosmic rays. Also in other embodiments described hereinbelow, similarly, the switching element may have any upper structure.

### Second Embodiment

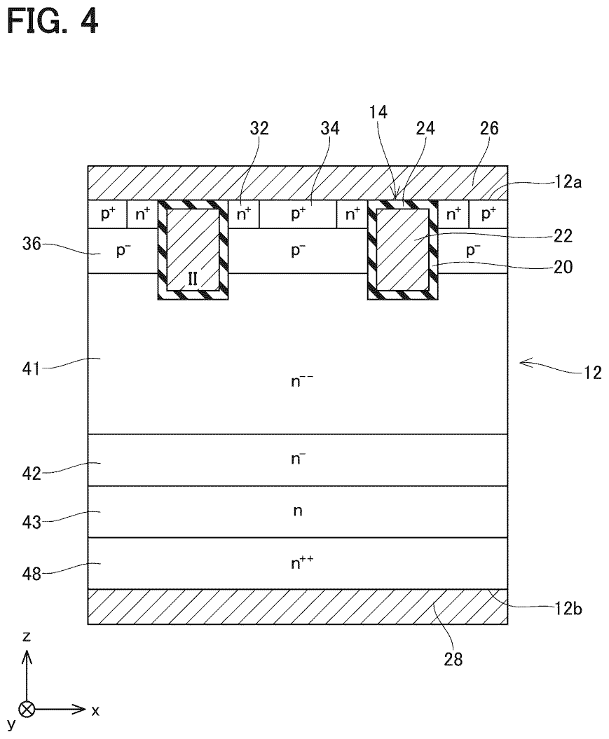

As shown in FIG. 4, a switching element according to a second embodiment has a third drift layer 43 between the second drift layer 42 and the drain layer 48. Except for having the third drift layer 43, the switching element of the second embodiment has the same structure as the switching element 10 of the first embodiment. The third drift layer 43 has an n-type impurity concentration that is 2 to 10 times the n-type impurity concentration B of the second drift layer 42. The third drift layer 43 is in contact with the second drift layer 42 from below. The drain layer 48 has an n-type impurity concentration higher than that of the third drift layer 43. The drain layer 48 is in contact with the third drift layer 43 from below. By adding the third drift layer 43 in this manner, the electric field generated inside the drift layer due to the cosmic rays can be made further small. Therefore, in the switching element of the second embodiment, the decrease in breakdown voltage due to the cosmic rays can be further suppressed.

### Third Embodiment

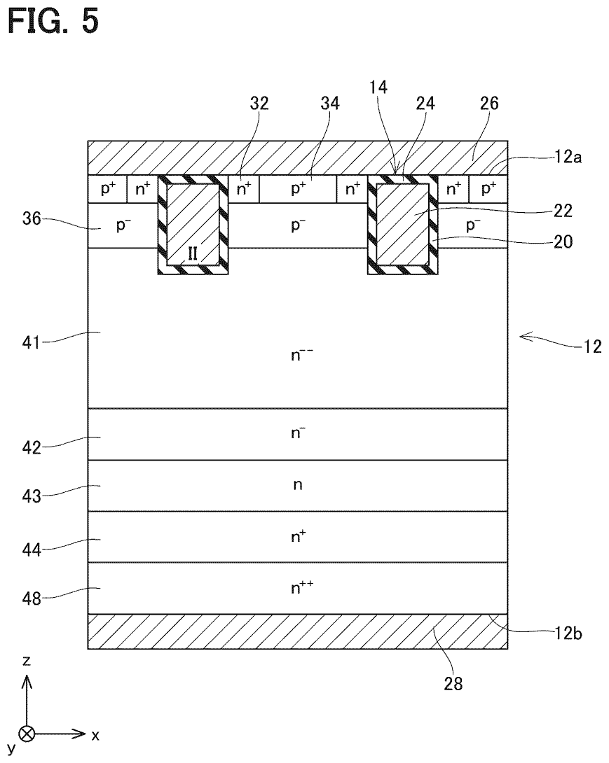

As shown in FIG. 5, a switching element according to a third embodiment has a fourth drift layer 44 between the third drift layer 43 and the drain layer 48. The fourth drift layer 44 has an n-type impurity concentration that is 2 to 10 times the n-type impurity concentration of the third drift layer 43. The fourth drift layer 44 is in contact with the third drift layer 43 from below. The drain layer 48 has an n-type impurity concentration higher than that of the fourth drift layer 44. The drain layer 48 is in contact with the fourth drift layer 44 from below. According to this configuration, the decrease in breakdown voltage due to the cosmic rays can be further suppressed. The switching element may include a multi-layer drift layer structure having more layers.

In each of the embodiments described above, the concentrations of the drift layers 41 to 44 may be adjusted during epitaxial growth, or may be adjusted by ion implantation after the epitaxial growth. In each of the embodiments described above, the n-type impurity concentration may change stepwise or along a gradient at the boundary between the adjacent drift layers.

While only the selected exemplary embodiments and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents.

What is claimed is:

1. A switching element comprising:
a semiconductor substrate made of silicon carbide; and
a gate electrode facing the semiconductor substrate through a gate insulating film, wherein
the semiconductor substrate includes:
a source layer of an n-type in contact with the gate insulating film;
a body layer of a p-type in contact with the gate insulating film and the source layer;
a first drift layer of the n-type that is in contact with the gate insulating film and the body layer, is separated from the source layer by the body layer, and has an n-type impurity concentration of 8×10¹⁵ cm⁻³ or more;
a second drift layer of the n-type that is in contact with the first drift layer from below and has an n-type impurity concentration of 12 to 26 times the n-type impurity concentration of the first drift layer; and
a drain layer of the n-type that is disposed below the second drift layer and has an n-type impurity concentration higher than that of the second drift layer.

2. The switching element according to claim 1, wherein
the n-type impurity concentration of the first drift layer is greater than 3×10¹⁶ cm⁻³.

3. The switching element according to claim 1, wherein
the semiconductor substrate further includes a third drift layer of the n-type that is in contact with the second drift layer from below and has an n-type impurity concentration of 2 to 10 times the n-type impurity concentration of the second drift layer,
the drain layer is disposed below the third drift layer, and
the n-type impurity concentration of the drain layer is higher than that of the third drift layer.

4. The switching element according to claim 1 for use at an altitude of a stratosphere or higher.

5. The switching element according to claim 1 for use in an outer space.
